(19) United States
(12) Patent Application Publication
(10) Pub. No.: US 2025/0323752 A1
(43) Pub. Date: Oct. 16, 2025

(54) BCC LOW CODING RATE DESIGNS FOR NEXT-GENERATION WLAN

(71) Applicant: MEDIATEK INC., Hsinchu City (TW)

(72) Inventors: Shengquan HU, San Jose, CA (US); Jianhan LIU, San Jose, CA (US); Thomas Edward PARE, Jr., San Jose, CA (US)

(21) Appl. No.: 18/866,183

(22) PCT Filed: Jun. 15, 2023
(86) PCT No.: PCT/CN2023/100455

§ 371 Date: Nov. 15, 2024

Related U.S. Application Data
(60) Provisional application No. 63/353,084, filed on Jun. 17, 2022.

(51) Int. Cl. H04L 1/00

(52) U.S. Cl. CPC H04L 1/0059; H04L 1/0003; H04L 1/0071

(57) ABSTRACT

Techniques pertaining to binary convolutional code (BCC) low coding rate designs for next-generation wireless local area networks (WLANs) are described. A processor of an apparatus (e.g., station (STA)) receives a string of input bits and codes the string of input bits. In coding the input bits, the processor encodes the input bits by a BCC encoder of the processor using a base code rate. The processor also repeats an output of the BCC encoder by a repetition circuit of the processor to result in an effective coding rate of the input bits that is lower than the base code rate.

### CROSS REFERENCE TO RELATED PATENT APPLICATION

The present disclosure is part of a non-provisional patent application claiming the priority benefit of U.S. Provisional Patent Application No. 63/353,084, filed 17 Jun. 2022, the content of which herein being incorporated by reference in its entirety.

### TECHNICAL FIELD

The present disclosure is generally related to wireless communications and, more particularly, to binary convolutional code (BCC) low coding rate designs for next-generation wireless local area networks (WLANs).

### BACKGROUND

Unless otherwise indicated herein, approaches described in this section are not prior art to the claims listed below and are not admitted as prior art by inclusion in this section.

With respect to wireless communications, such as in accordance with the Institute of Electrical and Electronics Engineers (IEEE) 802.11 standards, enhanced long range (ELR) Wi-Fi (or WiFi) is one of the key objectives for next-generation Wi-Fi. However, at the present time, designs of how to utilize BCC low coding rates in next-generation WLANs remains to be defined or otherwise specified. Therefore, there is a need for a solution of BCC low coding rate designs for next-generation WLANs.

### SUMMARY

The following summary is illustrative only and is not intended to be limiting in any way. That is, the following summary is provided to introduce concepts, highlights, benefits and advantages of the novel and non-obvious techniques described herein. Select implementations are further described below in the detailed description. Thus, the following summary is not intended to identify essential features of the claimed subject matter, nor is it intended for use in determining the scope of the claimed subject matter.

An objective of the present disclosure is to provide schemes, concepts, designs, techniques, methods and apparatuses pertaining to BCC low coding rate designs for next-generation WLANs. Moreover, new robust designs of modulation and coding scheme (MCS) with BCC low coding rate are also proposed under the various proposed schemes.

In one aspect, a method may involve receiving a string of input bits. The method may also involve coding the string of input bits by: (i) encoding the input bits by a BCC encoder of the processor using a base code rate; and (ii) repeating an output of the BCC encoder by a repetition circuit of the processor to result in an effective coding rate of the input bits that is lower than the base code rate.

In another aspect, an apparatus may include a transceiver configured to communicate wirelessly and a processor coupled to the transceiver. The processor may receive a string of input bits. The processor may also code the string of input bits by: (i) encoding the input bits by a BCC encoder of the processor using a base code rate; and (ii) repeating an output of the BCC encoder by a repetition circuit of the processor to result in an effective coding rate of the input bits that is lower than the base code rate.

It is noteworthy that, although description provided herein may be in the context of certain radio access technologies, networks and network topologies such as, Wi-Fi, the proposed concepts, schemes and any variation(s)/derivative(s) thereof may be implemented in, for and by other types of radio access technologies, networks and network topologies such as, for example and without limitation, Bluetooth, ZigBee, 5^{th} Generation (5G)/New Radio (NR), Long-Term Evolution (LTE), LTE-Advanced, LTE-Advanced Pro, Internet-of-Things (IoT), Industrial IoT (IIoT) and narrowband IoT (NB-IoT). Thus, the scope of the present disclosure is not limited to the examples described herein.

### BRIEF DESCRIPTION OF THE DRAWINGS

The accompanying drawings are included to provide a further understanding of the disclosure and are incorporated in and constitute a part of the present disclosure. The drawings illustrate implementations of the disclosure and, together with the description, serve to explain the principles of the disclosure. It is appreciable that the drawings are not necessarily in scale as some components may be shown to be out of proportion than the size in actual implementation to clearly illustrate the concept of the present disclosure.

FIG. 1 is a diagram of an example network environment in which various solutions and schemes in accordance with the present disclosure may be implemented.

FIG. 2 is a diagram of an example design under a proposed scheme in accordance with the present disclosure.

FIG. 3 is a diagram of an example design under a proposed scheme in accordance with the present disclosure.

FIG. 4 is a diagram of an example design under a proposed scheme in accordance with the present disclosure.

FIG. 5 is a diagram of an example design under a proposed scheme in accordance with the present disclosure.

FIG. 6 is a diagram of an example design under a proposed scheme in accordance with the present disclosure.

FIG. 7 is a diagram of an example design under a proposed scheme in accordance with the present disclosure.

FIG. 8 is a diagram of an example design under a proposed scheme in accordance with the present disclosure.

FIG. 9 is a diagram of an example design under a proposed scheme in accordance with the present disclosure.

FIG. 10 is a diagram of an example design under a proposed scheme in accordance with the present disclosure.

FIG. 11 is a block diagram of an example communication system in accordance with an implementation of the present disclosure.

FIG. 12 is a flowchart of an example process in accordance with an implementation of the present disclosure.

### DETAILED DESCRIPTION OF PREFERRED EMBODIMENTS

Detailed embodiments and implementations of the claimed subject matters are disclosed herein. However, it shall be understood that the disclosed embodiments and implementations are merely illustrative of the claimed subject matters which may be embodied in various forms. The present disclosure may, however, be embodied in many different forms and should not be construed as limited to the exemplary embodiments and implementations set forth herein. Rather, these exemplary embodiments and implementations are provided so that description of the present disclosure is thorough and complete and will fully convey the scope of the present disclosure to those skilled in the art. In the description below, details of well-known features and techniques may be omitted to avoid unnecessarily obscuring the presented embodiments and implementations.

### Overview

Implementations in accordance with the present disclosure relate to various techniques, methods, schemes and/or solutions pertaining to BCC low coding rate designs for next-generation WLANs. According to the present disclosure, a number of possible solutions may be implemented separately or jointly. That is, although these possible solutions may be described below separately, two or more of these possible solutions may be implemented in one combination or another.

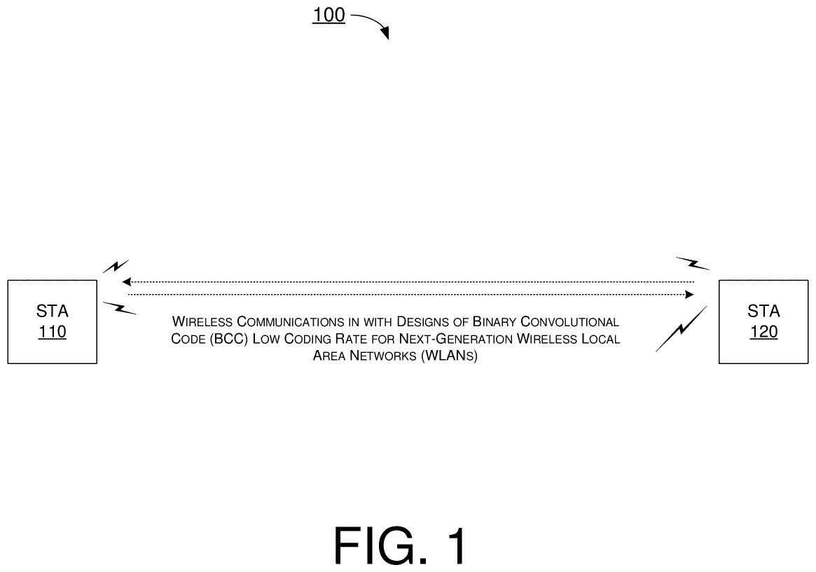

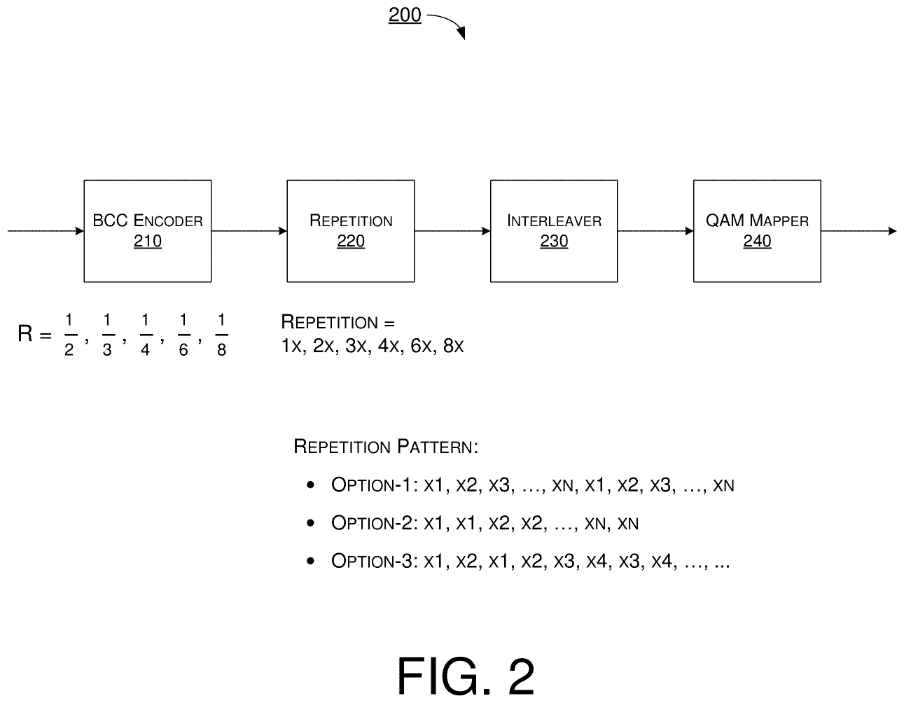

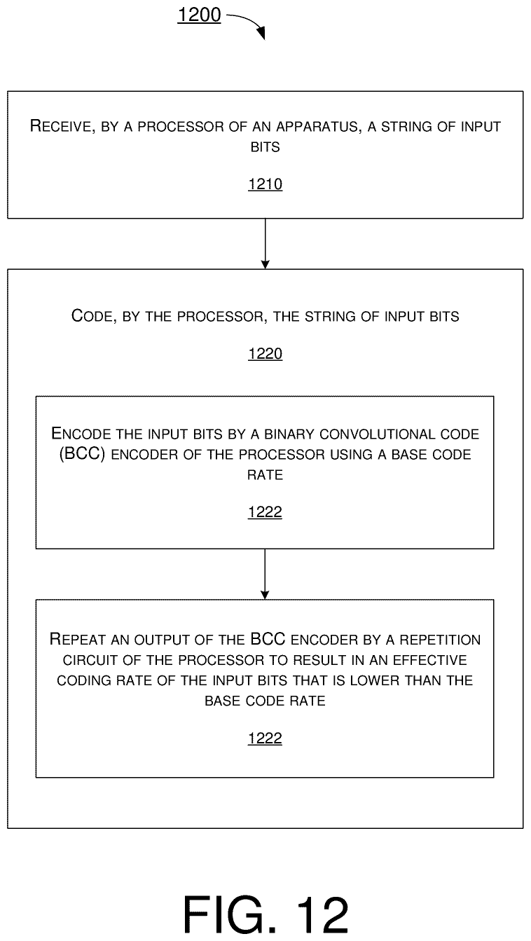

FIG. 1 illustrates an example network environment 100 in which various solutions and schemes in accordance with the present disclosure may be implemented. FIG. 2˜FIG. 12 illustrate examples of implementation of various proposed schemes in network environment 100 in accordance with the present disclosure. The following description of various proposed schemes is provided with reference to FIG. 1˜FIG. 12.

Referring to FIG. 1, network environment 100 may involve at least a station (STA) 110 communicating wirelessly with a STA 120. Either of STA 110 and STA 120 may be an access point (AP) STA or, alternatively, either of STA 110 and STA 120 may function as a non-AP STA. In some cases, STA 110 and STA 120 may be associated with a basic service set (BSS) in accordance with one or more IEEE 802.11 standards (e.g., IEEE 802.11be and future-developed standards). Each of STA 110 and STA 120 may be configured to communicate with each other by utilizing the BCC low coding rate designs for next-generation WLANs in accordance with various proposed schemes described below. That is, either or both of STA 110 and STA 120 may function as a “user” in the proposed schemes and examples described below. It is noteworthy that, while the various proposed schemes may be individually or separately described below, in actual implementations some or all of the proposed schemes may be utilized or otherwise implemented jointly. Of course, each of the proposed schemes may be utilized or otherwise implemented individually or separately.

FIG. 2 illustrates an example design 200 under a proposed scheme in accordance with the present disclosure. Design 200 pertains to BCC low coding rate and repetition. Referring to FIG. 2, various functions and/or operations involved in coding a string of data and/or information bits to achieve a BCC low coding rate for next-generation WLANs may involve a BCC encoding operation (e.g., by a BCC encoder 210), a repetition operation (e.g., by a repetition circuit 220), an interleaving function (e.g., by an interleaver 230) and a quadrature amplitude modulation (QAM) mapping function (e.g., by a QAM mapper 240). Under the proposed scheme, a base coding rate (R) utilized in design 200 may be ½, ⅓, ¼, ⅕, ⅙, 1/7 or ⅛. Moreover, under the proposed scheme, a repetition of codeword or output data utilized in design 200 may be 1× (repetition once), 2× (repetition twice), 3× (repetition thrice), 4× (repetition four times), 6× (repetition six times) or 8× (repetition eight times) to achieve an even lower effective coding rate that is lower than the base coding rate. Under the proposed scheme, there may be different options (Option-1, Option-2 and Option-3) regarding a repetition pattern. For an example, R=½ as the base code rate, with x2 repetition, in Option-1, the repetition pattern may be x1, x2, x3, . . . , xn, x1, x2, x3, . . . , xn. In Option-2, the repetition pattern may be x1, x1, x2, x2, . . . , xn, xn. In Option-3, the repetition pattern may be x1, x2, x1, x2, x3, x4, x3, x4, . . . x (n−1), xn.

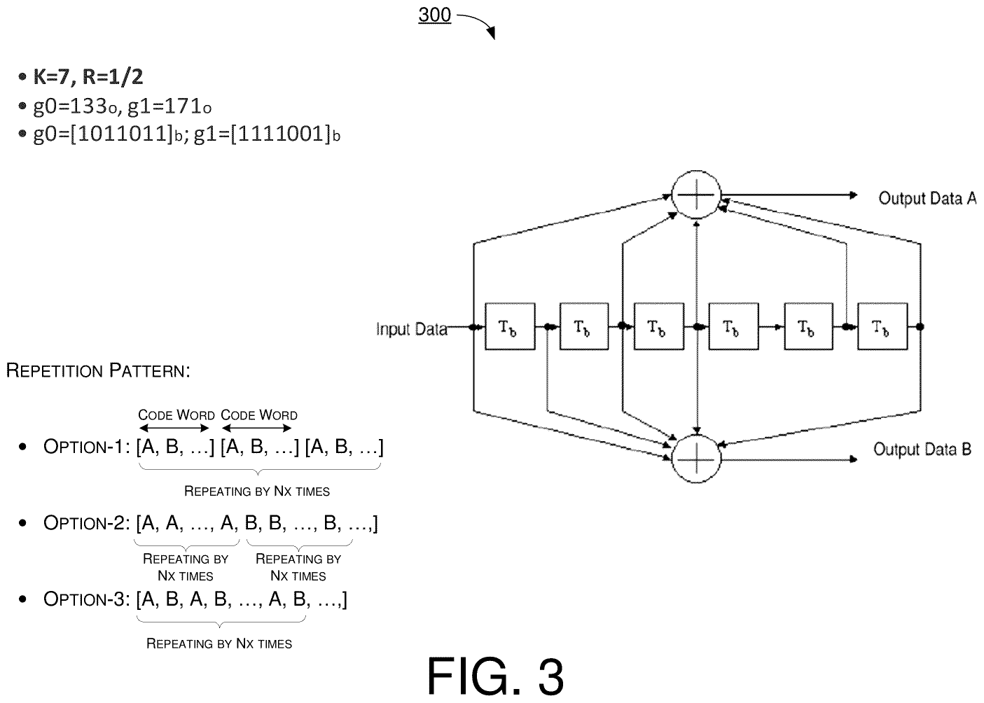

FIG. 3 illustrates an example design 300 under a proposed scheme in accordance with the present disclosure. In design 300, the base coding rate R=½ and the number of input bits into the encoder (e.g., BCC encoder 210) at one time (k)=7. Moreover, in design 300, the polynomials may include g0=133ₒ, g1=171ₒ, g0=[1011011]_{b}, g1=[1111001]_{b}. Under Option-1, after encoding the BCC codeword may be repeated by Nx times to result in a codeword repetition pattern of [A, B, . . . ] [A, B, . . . ], . . . , [A, B, . . . ]. Under Option-2, the output of each branch may be repeated by Nx times to result in a repetition pattern of [A, A, . . . , A, B, B, . . . , B, . . . ]. Under Option-3, the output from two branches may be repeated by Nx times to result in a repetition pattern of {A, B, A, B, . . . , A, B, . . . ].

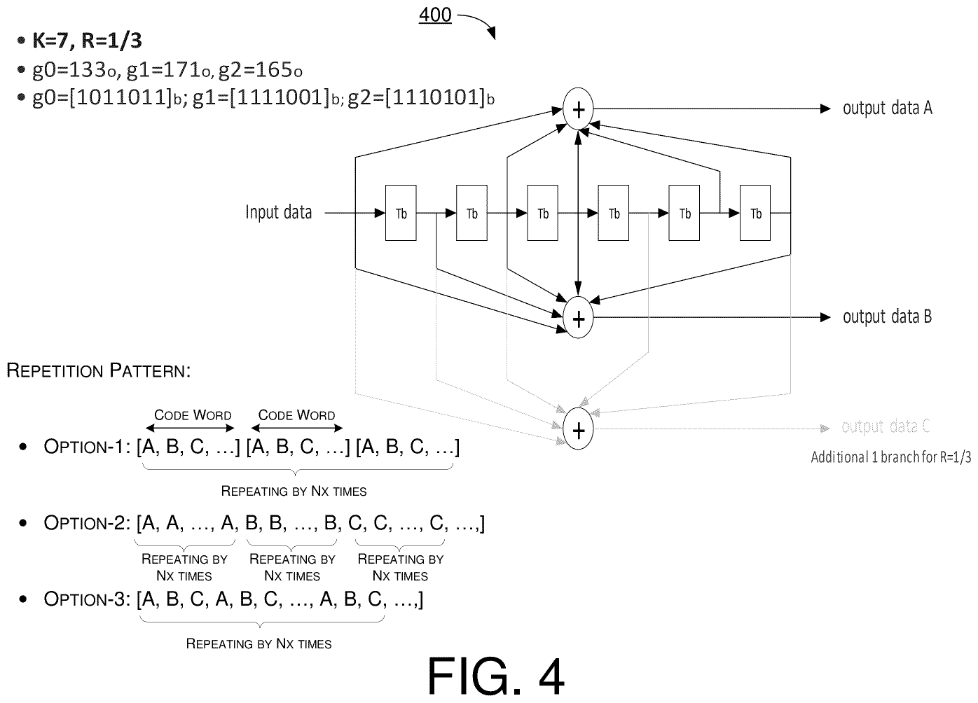

FIG. 4 illustrates an example design 400 under a proposed scheme in accordance with the present disclosure. In design 400, the base coding rate R=⅓ and k=7. Moreover, in design 400, the polynomials may include g0=133ₒ, g1=171ₒ, g2=165ₒ, g0=[1011011]_{b}, g1=[1111001]_{b}, g2=[1110101]_{b}. Under Option-1, after encoding the BCC codeword may be repeated by Nx times to result in a codeword repetition pattern of [A, B, C, . . . ] [A, B, C, . . . ], . . . , [A, B, C, . . . ]. Under Option-2, the output of each branch may be repeated by Nx times to result in a repetition pattern of [A, A, . . . , A, B, B, . . . , B, C, C, . . . , C, . . . ,]. Under Option-3, the output from three branches may be repeated by Nx times to result in a repetition pattern of {A, B, C, A, B, C, . . . , A, B, C, . . . ].

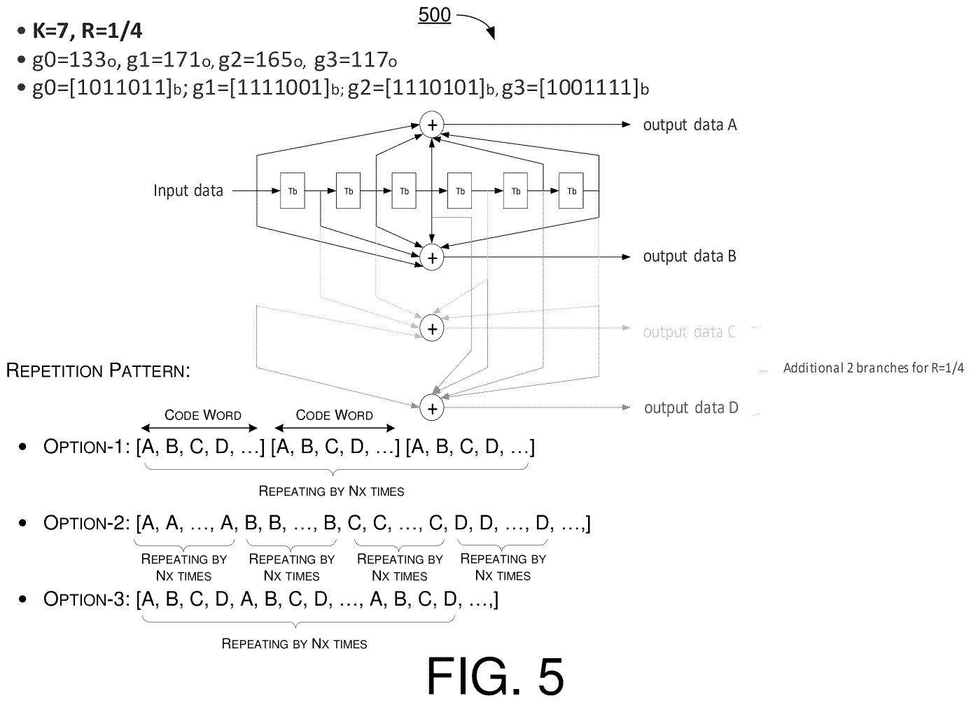

FIG. 5 illustrates an example design 500 under a proposed scheme in accordance with the present disclosure. In design 500, the base coding rate R=¼ and k=7. Moreover, in design 500, the polynomials may include g0=133ₒ, g1=171ₒ, g2=165ₒ, g3=117ₒ, g0=[1011011]_{b}, g1=[1111001]_{b}, g2=[1110101]_{b}, g3=[1001111]_{b}. It is noteworthy that alternative values for g3 may include [113, 123, 127, 135, 137, 145, 153, 155, 157, 173, 175]. Under Option-1, after encoding the BCC codeword may be repeated by Nx times to result in a codeword repetition pattern of [A, B, C, D, . . . ] [A, B, C, D, . . . ], . . . , [A, B, C, D, . . . ]. Under Option-2, the output of each branch may be repeated by Nx times to result in a repetition pattern of [A, A, . . . , A, B, B, . . . , B, C, C, . . . , C, D, D, . . . , D, . . . ]. Under Option-3, the output from four branches may be repeated by Nx times to result in a repetition pattern of {A, B, C, D, A, B, C, D, . . . , A, B, C, D, . . . ].

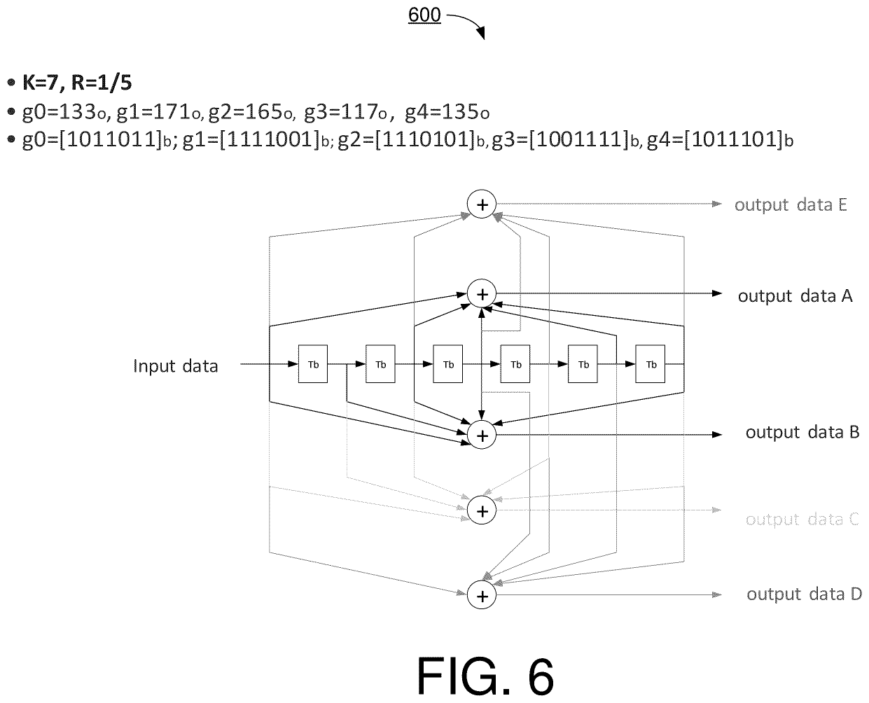

FIG. 6 illustrates an example design 600 under a proposed scheme in accordance with the present disclosure. In design 600, the base coding rate R=⅕ and k=7. Moreover, in design 600, the polynomials may include g₀=133ₒ, g1=171ₒ, g2=165ₒ, g3=117ₒ, g4=135ₒ, g0=[1011011]_{b}, g1=[1111001]_{b}, g2=[1110101]_{b}, g3=[1001111]_{b}, g4=[1011101]_{b}.

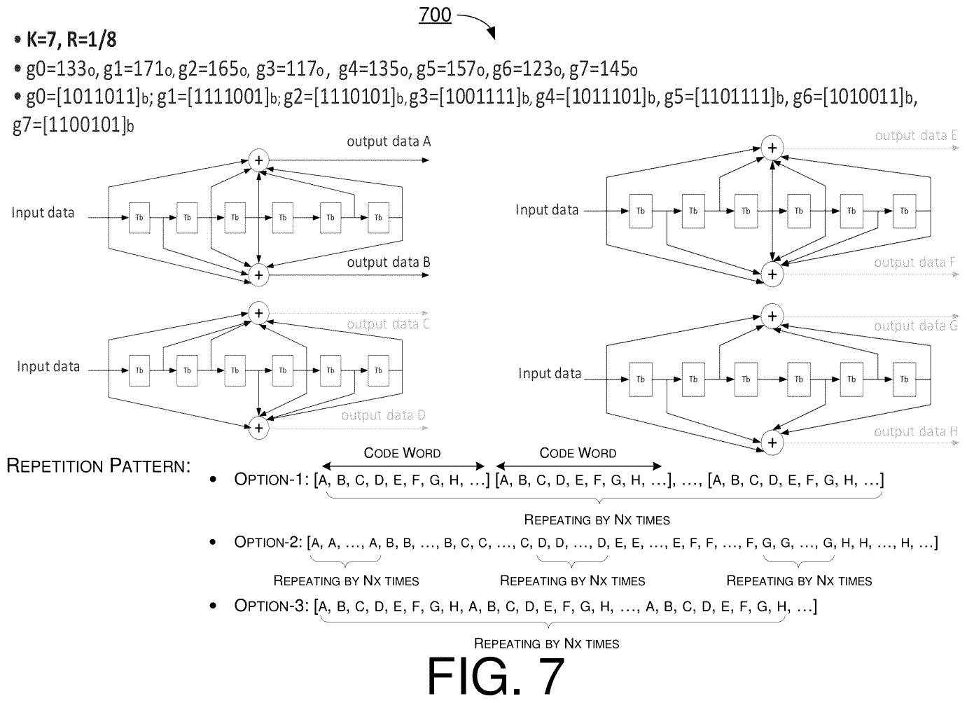

FIG. 7 illustrates an example design 700 under a proposed scheme in accordance with the present disclosure. In design 700, the base coding rate R=⅛ and k=7. Moreover, in design 700, the polynomials may include g0=133ₒ, g1=171ₒ, g2=165ₒ, g3=117ₒ, g4=135ₒ, g5=157ₒ, g6=123ₒ, g7=145ₒ, g0=[1011011_{b}, g1=[1111001]_{b}, g2=[1110101]_{b}, g3=[1001111]_{b}, g4=[1011101]_{b}, g5=[1101111]_{b}, g6=[1010011]_{b}, g7=[1100101]_{b}. Under Option-1, the BCC codeword after encoding may be repeated by Nx times to result in a codeword repetition pattern of [A, B, C, D, E, F, G, H, . . . ] [A, B, C, D, E, F, G, H, . . . ], . . . , [A, B, C, D, E, F, G, H, . . . ]. Under Option-2, the output of each branch may be repeated by Nx times to result in a repetition pattern of [A, A, . . . , A, B, B, . . . , B, C, C, . . . , C, D, D, . . . , D, E, E, . . . , E, F, F, . . . , F, G, G, . . . , G, H, H, . . . H, . . . ]. Under Option-3, the output from two branches may be repeated by Nx times to result in repetition pattern of {A, B, C, D, E, F, G, H, A, B, C, D, E, F, G, H, . . . , A, B, C, D, E, F, G, H, . . .].

Under various proposed schemes in accordance with the present disclosure, when k=7 and R=⅙, the polynomials may include g0=133ₒ, g1=171ₒ, g2=165ₒ, g3=117ₒ, g4=135ₒ, g5=157ₒ, g0=[1011011]_{b}, g1=[1111001]_{b}, g2=[1110101]_{b}, g3=[1001111]_{b}, g4=[1011101]_{b}, g5=[1101111]_{b}. Additionally, when k=7 and R= 1/7, the polynomials may include g0=133ₒ, g1=171ₒ, g2=165ₒ, g3=117ₒ, g4=135ₒ, g5=157ₒ, g6=123ₒ, g0=[1011011]_{b}, g1=[1111001]_{b}, g2=[1110101]_{b}, g3=[1001111]_{b}, g4=[1011101]_{b}, g5=[1101111]_{b}, g6=[1010011]_{b}. Moreover, when k=7 and R=⅛, the polynomials may include g0=133ₒ, g1=171ₒ, g2=165ₒ, g3=117ₒ, g4=135ₒ, g5=157ₒ, g6=123ₒ, g7=145ₒ, g0=[1011011]_{b}, g1=[1111001]_{b}, g2=[1110101]_{b}, g3=[1001111]_{b}, g4=[1011101]_{b}, g5=[1101111]_{b}, g6=[1010011]_{b}, g7=[1100101]_{b}.

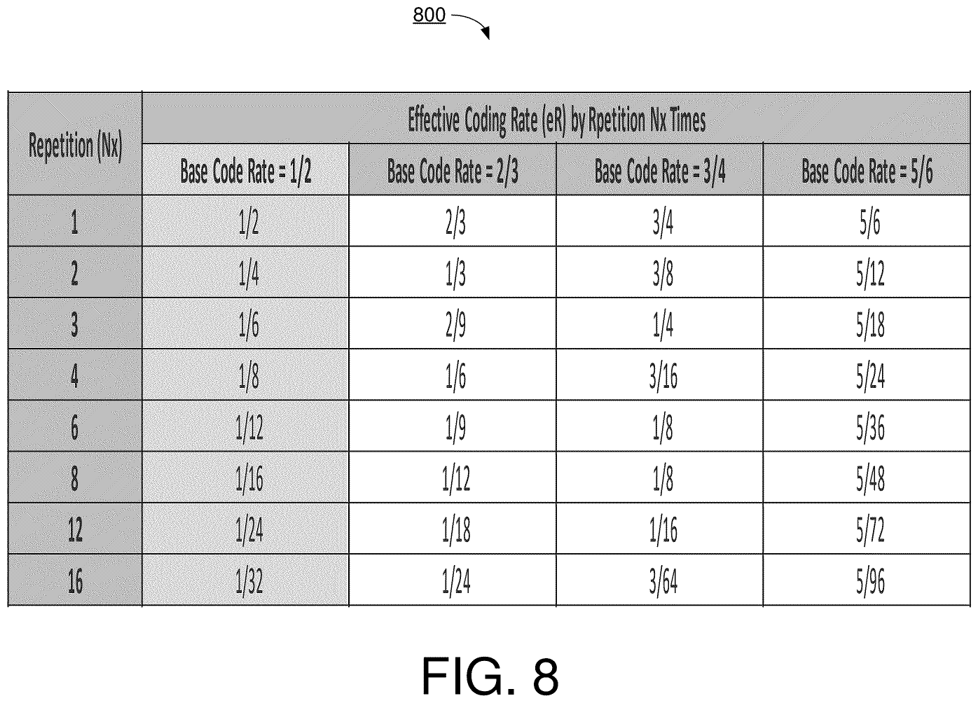

FIG. 8 illustrates an example design 800 under a proposed scheme in accordance with the present disclosure. Under the proposed scheme, the base code rate may be ½ or another rate, such as any of existing code rates in IEEE 802.11ax/be with R=½, ⅔, ¾, ⅚, and so on. The number of times of repetition (Nx) may be any integer such as Nx=2, 3, 4, . . . and so on. Referring to FIG. 8, a table in design 800 shows the effective coding rate (eR) according to different base rate (e.g., ½, ⅔, ¾, ⅚) and different number of repetitions (Nx). The low coding rate (LCR) may be applied to any modulations (e.g., binary phase-shift keying (BPSK), quadrature phase-shift keying (QPSK), 16 quadrature amplitude modulation (16 QAM) and the like).

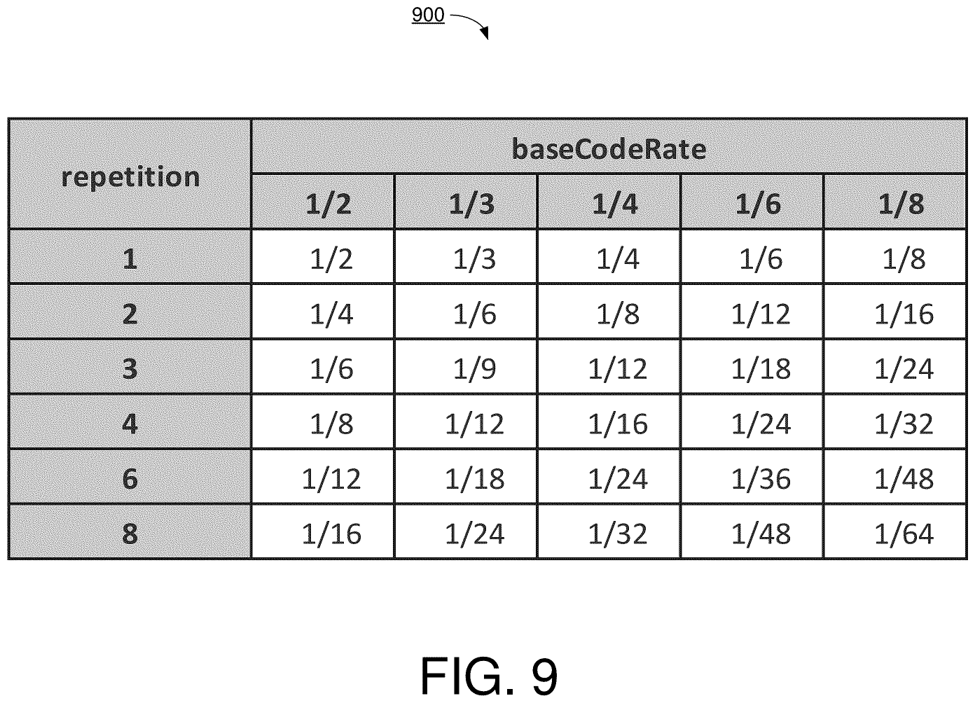

FIG. 9 illustrates an example design 900 under a proposed scheme in accordance with the present disclosure. Under the proposed scheme, different low coding rates eR=½, ⅓, ¼, ⅙, ⅛ may be utilized in addition to performing repetition in order to achieve an even lower effective coding rate (eR) such as eR=¼, ⅙, ⅛, 1/12, 1/16, 1/24, 1/32 or any other coding rate as listed in the table in design 900 shown in FIG. 9.

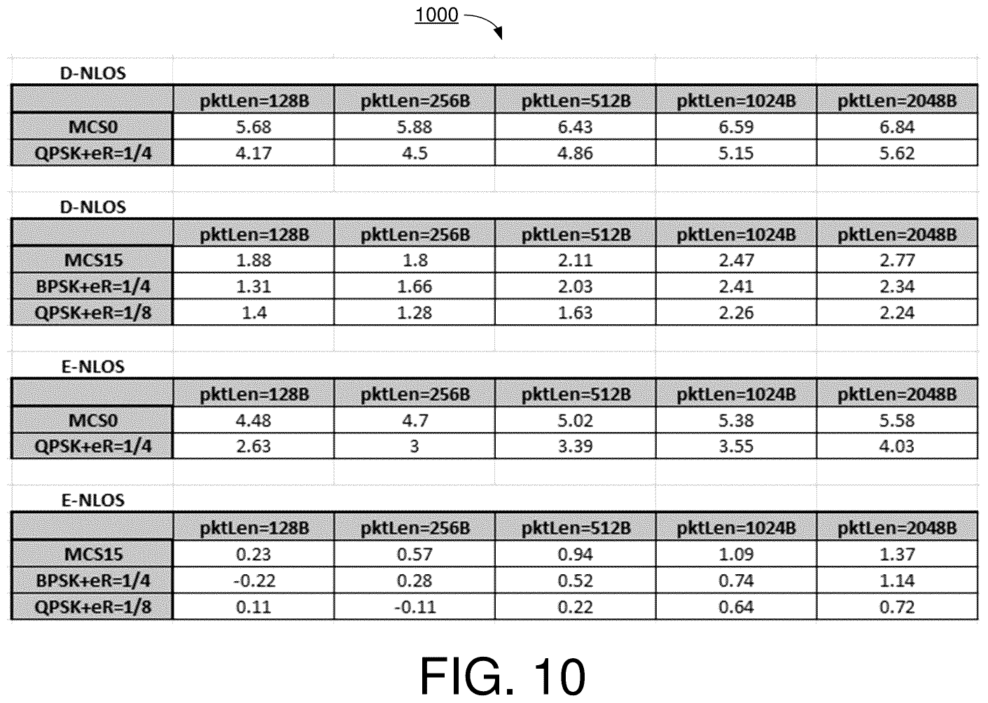

FIG. 10 illustrates an example design 1000 under a proposed scheme in accordance with the present disclosure. From various low coding rate simulations under the proposed schemes, it may be observed that, to achieve the same throughput or data rate, QPSK (which has a relatively higher modulation rate than BPSK) combined with a low coding rate tends to yield better performance than BPSK (which has a relatively lower modulation rate than QPSK) combined with R=½ or BPSK/R=½+dual carrier modulation (DCM). Parameters of the simulations include: 20 MHZ bandwidth, 242-tone resource units (RUs), one spatial stream (ss), single transmission and single reception (1T1R), estimated channel condition, BCC and no beamforming. Referring to FIG. 10, a table in design 100 summarizes some performance comparison results for the following comparisons: (1) IEEE 802.11be MCSO (BPSK+R=½) versus QPSK+R=¼; and (2) IEEE 802.11bc MCS15 (BPSK/R=½+DCM) versus QPSK+R=⅛. Accordingly, under the proposed scheme, the following options of MCS for low coding rates may be utilized to achieve robust and reliable communications: (a) a first new MCS (MCS-x) comprising QPSK+R=¼; and (b) a second new MCS (MCS-y) comprising QPSK+R=⅛.

### Illustrative Implementations

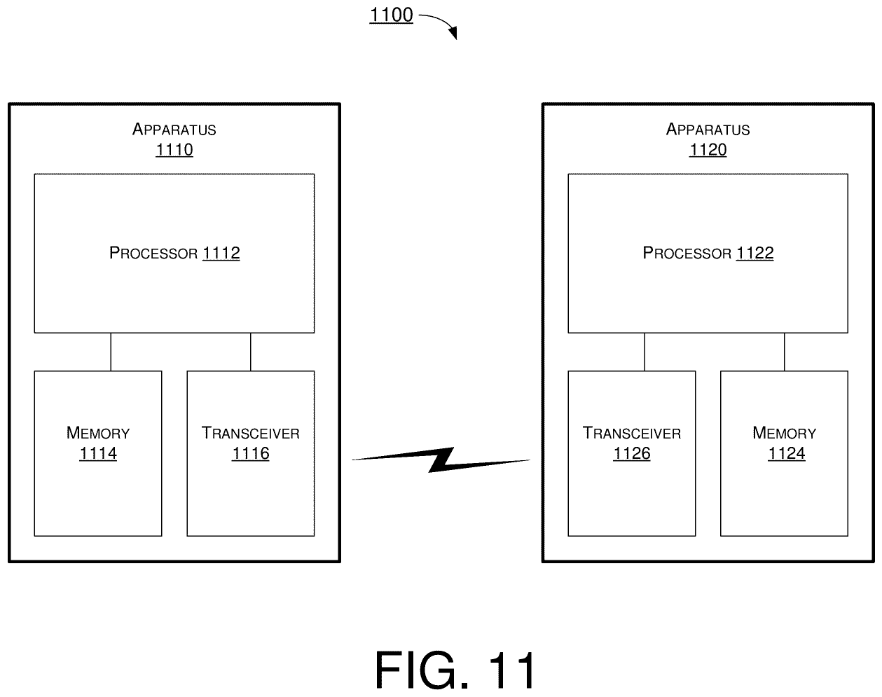

FIG. 11 illustrates an example system 1100 having at least an example apparatus 1110 and an example apparatus 1120 in accordance with an implementation of the present disclosure. Each of apparatus 1110 and apparatus 1120 may perform various functions to implement schemes, techniques, processes and methods described herein pertaining to BCC low coding rate designs for next-generation WLANs, including the various schemes described above with respect to various proposed designs, concepts, schemes, systems and methods described above as well as processes described below. For instance, apparatus 1110 may be implemented in STA 110 and apparatus 1120 may be implemented in STA 120, or vice versa.

Each of apparatus 1110 and apparatus 1120 may be a part of an electronic apparatus, which may be a non-AP STA or an AP STA, such as a portable or mobile apparatus, a wearable apparatus, a wireless communication apparatus or a computing apparatus. When implemented in a STA, each of apparatus 1110 and apparatus 1120 may be implemented in a smartphone, a smart watch, a personal digital assistant, a digital camera, or a computing equipment such as a tablet computer, a laptop computer or a notebook computer. Each of apparatus 1110 and apparatus 1120 may also be a part of a machine type apparatus, which may be an IoT apparatus such as an immobile or a stationary apparatus, a home apparatus, a wire communication apparatus or a computing apparatus. For instance, each of apparatus 1110 and apparatus 1120 may be implemented in a smart thermostat, a smart fridge, a smart door lock, a wireless speaker or a home control center. When implemented in or as a network apparatus, apparatus 1110 and/or apparatus 1120 may be implemented in a network node, such as an AP in a WLAN.

In some implementations, each of apparatus 1110 and apparatus 1120 may be implemented in the form of one or more integrated-circuit (IC) chips such as, for example and without limitation, one or more single-core processors, one or more multi-core processors, one or more reduced-instruction set computing (RISC) processors, or one or more complex-instruction-set-computing (CISC) processors. In the various schemes described above, each of apparatus 1110 and apparatus 1120 may be implemented in or as a STA or an AP. Each of apparatus 1110 and apparatus 1120 may include at least some of those components shown in FIG. 11 such as a processor 1112 and a processor 1122, respectively, for example. Each of apparatus 1110 and apparatus 1120 may further include one or more other components not pertinent to the proposed scheme of the present disclosure (e.g., internal power supply, display device and/or user interface device), and, thus, such component(s) of apparatus 1110 and apparatus 1120 are neither shown in FIG. 11 nor described below in the interest of simplicity and brevity.

In one aspect, each of processor 1112 and processor 1122 may be implemented in the form of one or more single-core processors, one or more multi-core processors, one or more RISC processors or one or more CISC processors. That is, even though a singular term “a processor” is used herein to refer to processor 1112 and processor 1122, each of processor 1112 and processor 1122 may include multiple processors in some implementations and a single processor in other implementations in accordance with the present disclosure. In another aspect, each of processor 1112 and processor 1122 may be implemented in the form of hardware (and, optionally, firmware) with electronic components including, for example and without limitation, one or more transistors, one or more diodes, one or more capacitors, one or more resistors, one or more inductors, one or more memristors and/or one or more varactors that are configured and arranged to achieve specific purposes in accordance with the present disclosure. In other words, in at least some implementations, each of processor 1112 and processor 1122 is a special-purpose machine specifically designed, arranged and configured to perform specific tasks including those pertaining to BCC low coding rate designs for next-generation WLANs in accordance with various implementations of the present disclosure.

In some implementations, apparatus 1110 may also include a transceiver 1116 coupled to processor 1112. Transceiver 1116 may include a transmitter capable of wirelessly transmitting and a receiver capable of wirelessly receiving data. In some implementations, apparatus 1120 may also include a transceiver 1126 coupled to processor 1122. Transceiver 1126 may include a transmitter capable of wirelessly transmitting and a receiver capable of wirelessly receiving data. It is noteworthy that, although transceiver 1116 and transceiver 1126 are illustrated as being external to and separate from processor 1112 and processor 1122, respectively, in some implementations, transceiver 1116 may be an integral part of processor 1112 as a system on chip (SoC), and transceiver 1126 may be an integral part of processor 1122 as a SoC.

In some implementations, apparatus 1110 may further include a memory 1114 coupled to processor 1112 and capable of being accessed by processor 1112 and storing data therein. In some implementations, apparatus 1120 may further include a memory 1124 coupled to processor 1122 and capable of being accessed by processor 1122 and storing data therein. Each of memory 1114 and memory 1124 may include a type of random-access memory (RAM) such as dynamic RAM (DRAM), static RAM (SRAM), thyristor RAM (T-RAM) and/or zero-capacitor RAM (Z-RAM). Alternatively, or additionally, each of memory 1114 and memory 1124 may include a type of read-only memory (ROM) such as mask ROM, programmable ROM (PROM), erasable programmable ROM (EPROM) and/or electrically erasable programmable ROM (EEPROM). Alternatively, or additionally, each of memory 1114 and memory 1124 may include a type of non-volatile random-access memory (NVRAM) such as flash memory, solid-state memory, ferroelectric RAM (FeRAM), magnetoresistive RAM (MRAM) and/or phase-change memory.

Each of apparatus 1110 and apparatus 1120 may be a communication entity capable of communicating with each other using various proposed schemes in accordance with the present disclosure. For illustrative purposes and without limitation, a description of capabilities of apparatus 1110, as STA 110, and apparatus 1120, as STA 120, is provided below. It is noteworthy that, although a detailed description of capabilities, functionalities and/or technical features of apparatus 1120 is provided below, the same may be applied to apparatus 1110 although a detailed description thereof is not provided solely in the interest of brevity. It is also noteworthy that, although the example implementations described below are provided in the context of WLAN, the same may be implemented in other types of networks.

Under various proposed schemes pertaining to BCC low coding rate designs for next-generation WLANs in accordance with the present disclosure, with apparatus 1110 implemented in or as STA 110 and apparatus 1120 implemented in or as STA 120 in network environment 100, processor 1112 of apparatus 1110 may receive a string of input bits. Moreover, processor 1112 may code the string of input bits. For instance, processor 1112 may encode the input bits by a BCC encoder 210 of processor 1112 using a base code rate. Moreover, processor 1112 may repeat an output of the BCC encoder by a repetition circuit 220 of processor 1112 to result in an effective coding rate of the input bits that is lower than the base code rate.

In some implementations, the base code rate may be ½, ⅓, ¼, ⅙, ⅛, ⅔, ¾ or ⅚.

In some implementations, in repeating the output of the BCC encoder, processor 1112 may repeat a codeword generated by the BCC encoder by a plurality of times, and wherein the codeword comprises a combination of output data from multiple output branches of the BCC encoder (e.g., Option-1 as described above).

Alternatively, in repeating the output of the BCC encoder, processor 1112 may repeat a respective output data of each output branch of the BCC encoder by a plurality of times to generate a repetition of a first output data of a first output branch of the BCC encoder by the plurality of times followed by a repetition of a second output data of a second output branch of the BCC encoder by the plurality of times (e.g., Option-2 as described above).

Still alternatively, in repeating the output of the BCC encoder, processor 1112 may repeat a combination of output data of multiple output branches of the BCC encoder by a plurality of times such that, in each repetition, the combination of output data comprises a first output data of a first output branch of the BCC encoder followed by a second output data of a second output branch of the BCC encoder (e.g., Option-3 as described above).

In some implementations, the base code rate may be ½, ⅔, ¾ or ⅚. In such cases, in repeating, processor 1112 may repeat 1 time, 2 times, 3 times, 4 times, 6 times, 8 times, 12 times or 16 times. Alternatively, or additionally, the base code rate may be ½, ⅓, ¼, ⅙ or ⅛. In such cases, in repeating, processor 1112 may repeat 1 time, 2 times, 3 times, 4 times, 6 times or 8 times.

In some implementations, in coding the string of input bits, processor 1112 may code the string of input bits with an MCS of QPSK with a base code rate of ¼. Alternatively, in coding the string of input bits, processor 1112 may code the string of input bits with an MCS of QPSK with a base code rate of ⅛.

In some implementations, in coding the string of input bits, processor 1112 perform additional operations. For instance, processor 1112 may interleave an output of the repetition circuit by an interleaver 230 of processor 1112. Furthermore, processor 1112 may map an output of the interleaver by a QAM mapper 240 of processor 1112.

### Illustrative Processes

FIG. 12 illustrates an example process 1200 in accordance with an implementation of the present disclosure. Process 1200 may represent an aspect of implementing various proposed designs, concepts, schemes, systems and methods described above. More specifically, process 1200 may represent an aspect of the proposed concepts and schemes pertaining to BCC low coding rate designs for next-generation WLANs in accordance with the present disclosure. Process 1200 may include one or more operations, actions, or functions as illustrated by one or more of blocks 1210 and 1220 as well as subblocks 1222 and 1224. Although illustrated as discrete blocks, various blocks of process 1200 may be divided into additional blocks, combined into fewer blocks, or eliminated, depending on the desired implementation. Moreover, the blocks/sub-blocks of process 1200 may be executed in the order shown in FIG. 12 or, alternatively in a different order. Furthermore, one or more of the blocks/sub-blocks of process 1200 may be executed repeatedly or iteratively. Process 1200 may be implemented by or in apparatus 1110 and apparatus 1120 as well as any variations thereof. Solely for illustrative purposes and without limiting the scope, process 1200 is described below in the context of apparatus 1110 implemented in or as STA 110 functioning as a non-AP STA and apparatus 1120 implemented in or as STA 120 functioning as an AP STA of a wireless network such as a WLAN in network environment 120 in accordance with one or more of IEEE 802.11 standards. Process 1200 may begin at block 1210.

At 1210, process 1200 may involve processor 1112 of apparatus 1110 receiving a string of input bits. Process 1200 may proceed from 1210 to 1220.

At 1220, process 1200 may involve processor 1112 coding the string of input bits. In coding the input bits, process 1200 may involve processor 1112 performing certain operations represented by 1222 and 1224.

At 1222, process 1200 may involve processor 1112 encoding the input bits by a BCC encoder 210 of processor 1112 using a base code rate. Process 1200 may proceed from 1222 to 1224.

At 1224, process 1200 may involve processor 1112 repeating an output of the BCC encoder by a repetition circuit 220 of processor 1112 to result in an effective coding rate of the input bits that is lower than the base code rate.

In some implementations, the base code rate may be ½, ⅓, ¼, ⅙, ⅛, ⅔, ¾, or ⅚.

In some implementations, in repeating the output of the BCC encoder, process 1200 may involve processor 1112 repeating a codeword generated by the BCC encoder by a plurality of times, and wherein the codeword comprises a combination of output data from multiple output branches of the BCC encoder (e.g., Option-1 as described above).

Alternatively, in repeating the output of the BCC encoder, process 1200 may involve processor 1112 repeating a respective output data of each output branch of the BCC encoder by a plurality of times to generate a repetition of a first output data of a first output branch of the BCC encoder by the plurality of times followed by a repetition of a second output data of a second output branch of the BCC encoder by the plurality of times (e.g., Option-2 as described above).

Still alternatively, in repeating the output of the BCC encoder, process 1200 may involve processor 1112 repeating a combination of output data of multiple output branches of the BCC encoder by a plurality of times such that, in each repetition, the combination of output data comprises a first output data of a first output branch of the BCC encoder followed by a second output data of a second output branch of the BCC encoder (e.g., Option-3 as described above).

In some implementations, the base code rate may be ½, ⅔, ¾ or ⅚. In such cases, in repeating, process 1200 may involve processor 1112 repeating 1 time, 2 times, 3 times, 4 times, 6 times, 8 times, 12 times or 16 times. Alternatively, or additionally, the base code rate may be ½, ⅓, ¼, ⅙ or ⅛. In such cases, in repeating, process 1200 may involve processor 1112 repeating 1 time, 2 times, 3 times, 4 times, 6 times or 8 times.

In some implementations, in coding the string of input bits, process 1200 may involve processor 1112 coding the string of input bits with an MCS of QPSK with a base code rate of ¼. Alternatively, in coding the string of input bits, process 1200 may involve processor 1112 coding the string of input bits with an MCS of QPSK with a base code rate of ⅛.

In some implementations, in coding the string of input bits, process 1200 may involve processor 1112 performing additional operations. For instance, process 1200 may involve processor 1112 interleaving an output of the repetition circuit by an interleaver 230 of processor 1112. Furthermore, process 1200 may involve processor 1112 mapping an output of the interleaver by a QAM mapper 240 of processor 1112.

### Additional Notes

The herein-described subject matter sometimes illustrates different components contained within, or connected with, different other components. It is to be understood that such depicted architectures are merely examples, and that in fact many other architectures can be implemented which achieve the same functionality. In a conceptual sense, any arrangement of components to achieve the same functionality is effectively “associated” such that the desired functionality is achieved. Hence, any two components herein combined to achieve a particular functionality can be seen as “associated with” each other such that the desired functionality is achieved, irrespective of architectures or intermedial components. Likewise, any two components so associated can also be viewed as being “operably connected”, or “operably coupled”, to each other to achieve the desired functionality, and any two components capable of being so associated can also be viewed as being “operably couplable”, to each other to achieve the desired functionality. Specific examples of operably couplable include but are not limited to physically mateable and/or physically interacting components and/or wirelessly interactable and/or wirelessly interacting components and/or logically interacting and/or logically interactable components.

Further, with respect to the use of substantially any plural and/or singular terms herein, those having skill in the art can translate from the plural to the singular and/or from the singular to the plural as is appropriate to the context and/or application. The various singular/plural permutations may be expressly set forth herein for sake of clarity.

Moreover, it will be understood by those skilled in the art that, in general, terms used herein, and especially in the appended claims, e.g., bodies of the appended claims, are generally intended as “open” terms, e.g., the term “including” should be interpreted as “including but not limited to,” the term “having” should be interpreted as “having at least,” the term “includes” should be interpreted as “includes but is not limited to,” etc. It will be further understood by those within the art that if a specific number of an introduced claim recitation is intended, such an intent will be explicitly recited in the claim, and in the absence of such recitation no such intent is present. For example, as an aid to understanding, the following appended claims may contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to implementations containing only one such recitation, even when the same claim includes the introductory phrases “one or more” or “at least one” and indefinite articles such as “a” or “an,” e.g., “a” and/or “an” should be interpreted to mean “at least one” or “one or more;” the same holds true for the use of definite articles used to introduce claim recitations. In addition, even if a specific number of an introduced claim recitation is explicitly recited, those skilled in the art will recognize that such recitation should be interpreted to mean at least the recited number, e.g., the bare recitation of “two recitations,” without other modifiers, means at least two recitations, or two or more recitations. Furthermore, in those instances where a convention analogous to “at least one of A, B, and C, etc.” is used, in general such a construction is intended in the sense one having skill in the art would understand the convention, e.g., “a system having at least one of A, B, and C” would include but not be limited to systems that have A alone, B alone, C alone, A and B together, A and C together, B and C together, and/or A, B, and C together, etc. In those instances where a convention analogous to “at least one of A, B, or C, etc.” is used, in general such a construction is intended in the sense one having skill in the art would understand the convention, e.g., “a system having at least one of A, B, or C” would include but not be limited to systems that have A alone, B alone, C alone, A and B together, A and C together, B and C together, and/or A, B, and C together, etc. It will be further understood by those within the art that virtually any disjunctive word and/or phrase presenting two or more alternative terms, whether in the description, claims, or drawings, should be understood to contemplate the possibilities of including one of the terms, either of the terms, or both terms. For example, the phrase “A or B” will be understood to include the possibilities of “A” or “B” or “A and B.”

From the foregoing, it will be appreciated that various implementations of the present disclosure have been described herein for purposes of illustration, and that various modifications may be made without departing from the scope and spirit of the present disclosure. Accordingly, the various implementations disclosed herein are not intended to be limiting, with the true scope and spirit being indicated by the following claims.

What is claimed is:

1. A method, comprising:
receiving, by a processor of an apparatus, a string of input bits; and
coding, by the processor, the string of input bits by performing operations comprising:
encoding the input bits by a binary convolutional code (BCC) encoder of the processor using a base code rate; and
repeating an output of the BCC encoder by a repetition circuit of the processor to result in an effective coding rate of the input bits that is lower than the base code rate.

2. The method of claim 1, wherein the base code rate comprises ½, ⅓, ¼, ⅙ or ⅛.

3. The method of claim 2, wherein the repeating of the output of the BCC encoder comprises repeating a codeword generated by the BCC encoder by a plurality of times, and wherein the codeword comprises a combination of output data from multiple output branches of the BCC encoder.

4. The method of claim 2, wherein the repeating of the output of the BCC encoder comprises repeating a respective output data of each output branch of the BCC encoder by a plurality of times to generate a repetition of a first output data of a first output branch of the BCC encoder by the plurality of times followed by a repetition of a second output data of a second output branch of the BCC encoder by the plurality of times.

5. The method of claim 2, wherein the repeating of the output of the BCC encoder comprises repeating a combination of output data of multiple output branches of the BCC encoder by a plurality of times such that, in each repetition, the combination of output data comprises a first output data of a first output branch of the BCC encoder followed by a second output data of a second output branch of the BCC encoder.

6. The method of claim 1, wherein the base code rate comprises ½, ⅔, ¾ or ⅚, and wherein the repeating comprises repeating 1 time, 2 times, 3 times, 4 times, 6 times, 8 times, 12 times or 16 times.

7. The method of claim 1, wherein the base code rate comprises ½, ⅓, ¼, ⅙ or ⅛, and wherein the repeating comprises repeating 1 time, 2 times, 3 times, 4 times, 6 times or 8 times.

8. The method of claim 1, wherein the coding of the string of input bits comprises coding the string of input bits with a modulation and coding scheme (MCS) of quadrature phase-shift keying (QPSK) with a base code rate of ¼.

9. The method of claim 1, wherein the coding of the string of input bits comprises coding the string of input bits with a modulation and coding scheme (MCS) of quadrature phase-shift keying (QPSK) with a base code rate of 1/8.

10. The method of claim 1, wherein the coding of the string of input bits further comprise:
interleaving an output of the repetition circuit by an interleaver of the processor; and
mapping an output of the interleaver by a quadrature amplitude modulation (QAM) mapper of the processor.

11. An apparatus, comprising:
a transceiver configured to communicate wirelessly; and
a processor coupled to the transceiver and configured to perform operations comprising:
receiving a string of input bits; and
coding the string of input bits by performing operations comprising:
encoding the input bits by a binary convolutional code (BCC) encoder of the processor using a base code rate; and
repeating an output of the BCC encoder by a repetition circuit of the processor to result in an effective coding rate of the input bits that is lower than the base code rate.

12. The apparatus of claim 11, wherein the base code rate comprises ½, ⅓, ¼, ⅙ or ⅛.

13. The apparatus of claim 12, wherein the repeating of the output of the BCC encoder comprises repeating a codeword generated by the BCC encoder by a plurality of times, and wherein the codeword comprises a combination of output data from multiple output branches of the BCC encoder.

14. The apparatus of claim 12, wherein the repeating of the output of the BCC encoder comprises repeating a respective output data of each output branch of the BCC encoder by a plurality of times to generate a repetition of a first output data of a first output branch of the BCC encoder by the plurality of times followed by a repetition of a second output data of a second output branch of the BCC encoder by the plurality of times.

15. The apparatus of claim 12, wherein the repeating of the output of the BCC encoder comprises repeating a combination of output data of multiple output branches of the BCC encoder by a plurality of times such that, in each repetition, the combination of output data comprises a first output data of a first output branch of the BCC encoder followed by a second output data of a second output branch of the BCC encoder.

16. The apparatus of claim 11, wherein the base code rate comprises ½, ⅔, ¾ or ⅚, and wherein the repeating comprises repeating 1 time, 2 times, 3 times, 4 times, 6 times, 8 times, 12 times or 16 times.

17. The apparatus of claim 11, wherein the base code rate comprises ½, ⅓, ¼, ⅙ or ⅛, and wherein the repeating comprises repeating 1 time, 2 times, 3 times, 4 times, 6 times or 8 times.

18. The apparatus of claim 11, wherein the coding of the string of input bits comprises coding the string of input bits with a modulation and coding scheme (MCS) of quadrature phase-shift keying (QPSK) with a base code rate of ¼.

19. The apparatus of claim 11, wherein the coding of the string of input bits comprises coding the string of input bits with a modulation and coding scheme (MCS) of quadrature phase-shift keying (QPSK) with a base code rate of ⅛.

20. The apparatus of claim 11, wherein, in coding the string of input bits, the processor is further configured to perform operations comprising:
interleaving an output of the repetition circuit by an interleaver of the processor; and
mapping an output of the interleaver by a quadrature amplitude modulation (QAM) mapper of the processor.
